(19) United States
(12) Patent Application Publication
(10) Pub. No.: US 2025/0119058 A1
(43) Pub. Date: Apr. 10, 2025

(54) MULTI-PHASE POWER SUPPLY SYSTEM AND CONTROL OF DYNAMIC LOAD

(71) Applicant: Infineon Technologies Austria AG, Villach (AT)

(72) Inventors: Luca PELUSO, Villach (AT); Darryl TSCHIRHART, Newmarket (CA); Roberto RIZZOLATTI, Villach (AT)

(21) Appl. No.: 18/377,037

(22) Filed: Oct. 5, 2023

(51) Int. Cl. H02M 3/00; H02M 3/158; H05K 1/02; H05K 1/18; H05K 7/14; H05K 7/20

(52) U.S. Cl. CPC H02M 3/003; H02M 3/158; H05K 1/0201; H05K 1/181; H05K 7/1427; H05K 7/209; H05K 2201/066; H05K 2201/10053

(57) ABSTRACT

A power converter assembly includes a first circuit board and a second circuit board. The first circuit board includes power converter circuitry operative to control conversion of an input voltage into an output voltage. The second circuit board is disposed substantially orthogonal to the first circuit board. The second circuit board is operative to: i) receive the output voltage, and ii) convey the output voltage to an output of the second circuit board such as a host circuit board. Additionally, the power converter assembly can be configured to include an over-mold assembly operative to provide connectivity between the first circuit board and the second circuit board. More specifically, the over-mold assembly can be configured to include an inductor component to output the output voltage to the second circuit board based on current received by the inductor component from the input voltage received over a first electrically conductive path between the second circuit board and the first circuit board.

### BACKGROUND

One type of conventional power converter is a buck converter. In general, to maintain an output voltage within a desired range, a controller associated with the buck converter compares the magnitude of a generated output voltage to a setpoint reference voltage. Based on a respective error voltage, the controller modifies a respective switching frequency and/or pulse width modulation associated with activating high side switch circuitry and low side switch circuitry in the buck converter to maintain a magnitude of the output voltage.

In certain instances, the conventional controller controls operation of the buck converter and generation of the output voltage based on an amount of output current supplied by a generated output voltage to a load. For example, conventional techniques include receiving a so-called VID (Voltage Identification) from a load such as a processor being powered by the output voltage. The VID indicates a setpoint voltage in which to produce the output voltage to power the load. The magnitude of the VID setting (such as setpoint reference voltage) may vary depending on a magnitude of the output current. In a manner as previously discussed, the controller of the power supply can be configured to regulate a magnitude of the output voltage supplied to the load based on a target setpoint voltage derived from the received VID value.

### BRIEF DESCRIPTION

Implementation of clean energy (or green technology) is very important to reduce our impact as humans on the environment. In general, clean energy includes any evolving methods and materials to reduce an overall toxicity to the environment as caused by energy consumption. This disclosure includes the observation that raw energy, such as received from green energy sources or non-green energy sources, typically needs to be converted into an appropriate form (such as desired AC voltage, DC voltage, etc.) before it can be used to power end devices such as servers, computers, mobile communication devices, etc. Regardless of whether energy is received from green energy sources or non-green energy sources, it is desirable to make most efficient use of raw energy provided by such systems to reduce our impact on the environment. This disclosure contributes to reducing our carbon footprint (and green energy) via more efficient energy conversion.

This disclosure further includes the observation that an important aspect of designing a power system is to consider provide optimal delivery of power via control of multiple power converter phases.

More specifically, a power converter assembly comprises: a first circuit board including power converter circuitry operative to convert an input voltage into an output voltage; and a second circuit board disposed substantially orthogonal to the first circuit board, the second circuit board operative to: i) receive the output voltage, and ii) convey the output voltage to an output of the second circuit board.

The power converter assembly can be configured to include an inductor assembly including an input node and an output node, the input node coupled to the first circuit board to receive input current sourced from the input voltage, the output node coupled to the second circuit board to supply the output voltage to the second circuit board. The power converter assembly further can be configured to include multiple switches affixed to the first circuit board and/or the second circuit board, the multiple switches operative to receive control signals from a controller, the control signals operative to control conveyance of the input current through the inductor assembly to produce the output voltage supplied to the second circuit board. The inductor assembly can be configured to include: a mass of magnetic permeable material; and a first electrically conductive path extending through the mass of magnetic permeable material. The inductor assembly can be fabricated in an over-mold assembly, the over-mold assembly including: a second electrically conductive element providing connectivity between the first circuit board and the second circuit board, the second electrically conductive element operative to convey the input voltage from the second circuit board to the first circuit board; and a third electrically conductive element disposed between the first circuit board and the second circuit board, the second electrically conductive element operative to convey a reference voltage from the second circuit board to the first circuit board.

In accordance with still further examples, the power converter assembly can be configured to include: an inductor assembly coupled to the first circuit board and the second circuit board, the inductor assembly operative to convert the input voltage into the output voltage based on control of current received from the input voltage through an electrically conductive path of the inductor assembly to the second circuit board; and a heat sink assembly, a first portion of the heat sink assembly coupled to a surface of the first circuit board, the first circuit board disposed between the first portion of the heat sink assembly and the inductor assembly. A second portion of the heat sink assembly can be to a surface of the inductor assembly, the inductor assembly disposed between a second portion of the heat sink assembly and the second circuit board.

In yet further examples, the power converter assembly as discussed herein includes: an over-mold assembly operative to provide connectivity between the first circuit board and the second circuit board, the over-mold assembly including an inductor assembly and multiple connector components; the inductor assembly is operative to output the output voltage to the second circuit board based on current inputted to the inductor assembly from the input voltage; and the multiple connector components include: i) a first electrically conductive element providing conveyance of the input voltage from the second circuit board to the first circuit board, and ii) a second electrically conductive element providing conveyance of a reference voltage associated with the input voltage from the second circuit board to the first circuit board.

In accordance with still further examples, the second circuit board includes a connector interface providing connectivity of an edge of the second circuit board to the first circuit board to convey signals received from a host substrate to the first circuit board.

Yet further, the first circuit board can be configured to include a connector interface providing connectivity of an edge of the first circuit board to the host substrate, the connector interface operative to convey signals received from a host substrate to the power converter circuitry on the first circuit board, the second circuit board affixed to the host substrate. The connector interface can be configured to convey the input voltage from the host substrate to the power converter circuitry of the first circuit board.

In accordance with further examples, the power converter assembly includes: an inductor assembly coupled to the first circuit board and the second circuit board, the inductor assembly including an electrically conductive path operative to convert current received from the input voltage into the output voltage, the inductor assembly including first magnetic permeable material surrounding a first portion of the electrically conductive path, the inductor component including second magnetic permeable material surrounding a second portion of the electrically conductive path. A magnetic permeability of the first magnetic permeable material is optionally different than a magnetic permeability of the second magnetic permeable material. The first portion of the inductor assembly extends axially in a first direction; the second portion of the inductor assembly extends axially in a second direction different than the first direction.

The power converter assembly further can be configured to include: an inductor assembly including magnetic permeable material and an electrically conductive path, the electrically conductive path providing direct connectivity between the first circuit board and the second circuit board; a spacing between the magnetic permeable material and a surface of the second circuit board; and multiple circuit components directly coupled to the surface of the second circuit board, the circuit components residing in the spacing between the magnetic permeable material and the surface of the second circuit board.

Further examples of the power converter assembly as discussed herein include a flexible hinge connector providing connectivity between an edge of the first circuit board and an edge of the second circuit board, the flexible hinge connector operative to convey signals between the first circuit board and the second circuit board. The first circuit board includes a first surface pad, a second surface pad, and a third surface pad; the second circuit board includes a fourth surface pad, a fifth surface pad, and a sixth surface pad; the fourth surface pad of the second circuit board is operative to output the input voltage over a first electrically conductive path from the second circuit board to the third surface pad of the first circuit board; a second electrically conductive path disposed between the fifth surface pad of the second circuit board and the second surface pad of the first circuit board is operative to provide a reference voltage from the second circuit board to the first circuit board; and the first surface pad of the first circuit board is operative to output current derived from the input voltage over a third electrically conductive path to the sixth surface pad of the second circuit board, the third electrically conductive path being an inductor component. Note that the implementation of 6 surface pads as previously discussed is just an example and that an implementation may include any number of surface pads and accompanying connectivity as desired by a designer. Note further that the designer may include other pads to mount other components as may be desired.

In yet further examples, the power converter assembly includes a transformer assembly coupled to the first circuit board and the second circuit board, the transformer assembly including: i) a first electrically conductive path extending through magnetic permeable material, the first electrically conductive path being a primary winding operative to convert current received from the input voltage into the output voltage, and ii) a second electrically conductive path disposed in parallel to the first electrically conductive path and extending through the magnetic permeable material, the second electrically conductive path being a secondary winding magnetically coupled to the primary winding. The secondary winding can be disposed in a circuit path connecting multiple secondary windings in series.

In further examples, the power converter assembly as described herein includes a heat sink assembly directly coupled to a surface of the first circuit board, the heat sink assembly including a conduit, fluid flow through the conduit operative to receive heat dissipated from the first circuit board. The power converter assembly can be configured to include: a third circuit board including power converter circuitry operative to control conversion of the input voltage into the output voltage; a fourth circuit board disposed substantially orthogonal to the third circuit board, the fourth circuit board operative to: i) receive the output voltage, and ii) convey the output voltage to an output of the fourth circuit board; and wherein the heat sink assembly is directly coupled to a surface of the third circuit board, the fluid flow through the conduit operative to receive heat dissipated from the third circuit board.

Still further examples discussed herein include a method comprising: receiving a first circuit board including power converter circuitry operative to control conversion of an input voltage into an output voltage; receiving a second circuit board operative to: i) receive the output voltage, and ii) convey the output voltage to an output of the second circuit board; and fabricating the second circuit board to be substantially orthogonal to the first circuit board.

Note that although examples as discussed herein are applicable to power converters, the concepts disclosed herein may be advantageously applied to any other suitable topologies as well as general power supply control applications.

Note that any of the resources as discussed herein can include one or more computerized devices, controller, mobile communication devices, servers, base stations, wireless communication equipment, communication management systems, workstations, user equipment, handheld or laptop computers, or the like to carry out and/or support any or all of the method operations disclosed herein. In other words, one or more computerized devices or processors can be programmed and/or configured to operate as explained herein to carry out the different examples as described herein.

Yet other examples herein include software programs to perform the steps and operations summarized above and disclosed in detail below. One such example comprises a computer program product including a non-transitory computer-readable storage medium (i.e., any computer readable hardware storage medium) on which software instructions are encoded for subsequent execution. The instructions, when executed in a computerized device (hardware) having a processor, program and/or cause the processor (hardware) to perform the operations disclosed herein. Such arrangements are typically provided as software, code, instructions, and/or other data (e.g., data structures) arranged or encoded on a non-transitory computer readable storage medium such as an optical medium (e.g., CD-ROM), floppy disk, hard disk, memory stick, memory device, etc., or other a medium such as firmware in one or more ROM, RAM, PROM, etc., or as an Application Specific Integrated Circuit (ASIC), etc. The software or firmware or other such configurations can be installed onto a computerized device to cause the computerized device to perform the techniques explained herein.

Accordingly, examples herein are directed to methods, systems, computer program products, etc., that support operations as discussed herein.

One example herein includes a computer readable storage medium and/or system having instructions stored thereon. The instructions, when executed by computer processor hardware, cause the computer processor hardware (such as one or more co-located or disparately located processor devices) to: determine a magnitude of first output current supplied from a first power converter to a dynamic load; determine a magnitude of second output current supplied from a second power converter to power the dynamic load; and control a magnitude of the first output current with respect to a magnitude of the second content output current depending on a magnitude of total output current consumed by the dynamic load.

The ordering of the steps above has been added for clarity sake. Note that any of the processing operations as discussed herein can be performed in any suitable order.

Other examples of the present disclosure include software programs and/or respective hardware to perform any of the method example steps and operations summarized above and disclosed in detail below.

It is to be understood that the system, method, apparatus, instructions on computer readable storage media, etc., as discussed herein also can be implemented strictly as a software program, firmware, as a hybrid of software, hardware and/or firmware, or as hardware alone such as within a processor (hardware or software), or within an operating system or a within a software application.

As discussed herein, techniques herein are well suited for use in the field of implementing one or more power converters to deliver current to a load. However, it should be noted that examples herein are not limited to use in such applications and that the techniques discussed herein are well suited for other applications as well.

Additionally, note that although each of the different features, techniques, configurations, etc., herein may be discussed in different places of this disclosure, it is intended, where suitable, that each of the concepts can optionally be executed independently of each other or in combination with each other. Accordingly, the one or more present inventions as described herein can be implemented and viewed in many different ways.

Also, note that this preliminary discussion of examples herein (BRIEF DESCRIPTION OF EXAMPLES) purposefully does not specify every example and/or incrementally novel aspect of the present disclosure or claimed invention(s). Instead, this brief description only presents general examples and corresponding points of novelty over conventional techniques. For additional details and/or possible perspectives (permutations) of the invention(s), the reader is directed to the Detailed Description section (which is a summary of examples) and corresponding figures of the present disclosure as further discussed below.

### BRIEF DESCRIPTION OF THE DRAWINGS

FIG. 1A is an example side view diagram of a power supply assembly including a first circuit board disposed orthogonal to a second circuit board as described herein.

FIG. 1B is an example 3-D (three-dimensional) diagram of an inductor assembly as described herein.

FIG. 2 is an example diagram illustrating implementation of a power converter phase to provide power to a dynamic load as discussed herein.

FIG. 3 is an example side view diagram of a power supply assembly as described herein.

FIG. 4 is an example diagram illustrating a power supply assembly as described herein

FIG. 5A is a side view diagram of a power supply assembly as described herein.

FIG. 5B is a top view diagram of a power supply assembly as described herein.

FIG. 5C is an example first side view diagram of a power supply assembly as described herein.

FIG. 5D is an example second side view diagram of a power supply assembly as described herein.

FIG. 6A is an example 3-D diagram of a circuit path assembly as described herein.

FIG. 6B is an example side view diagram of the circuit path assembly of FIG. 6A is described herein.

FIG. 7 is an example side view diagram illustrating implementation of a power supply assembly as described herein.

FIG. 8A is an example side view diagram illustrating implementation of a power supply assembly as described herein.

FIG. 8B is an example diagram view of input-output pads associated with the power supply assembly as described through them.

FIG. 8C an example diagram illustrating a side view diagram of a circuit path assembly as described herein.

FIG. 9 is an example side view diagram illustrating implementation of a power supply assembly including multiple instances of magnetic permeable material permeability as described herein.

FIG. 10 is an example side view diagram illustrating implementation of the power supply assembly as described herein.

FIG. 11 is an example side view diagram illustrating implementation of a power supply assembly as described herein.

FIG. 12A is an example side view diagram illustrating implementation of a power supply assembly as described herein.

FIG. 12B is an example diagram illustrating implementation of multiple circuit boards and a respective flexible connector as described herein.

FIGS. 13A, 13B, and 13C are example diagrams illustrating fabrication of a power supply assembly as described herein.

FIG. 14 is an example 3-D view diagram illustrating a transformer assembly as described herein.

FIG. 15 is an example diagram illustrating connectivity amongst multiple power supply assemblies to provide a trans-inductance voltage regulator as described herein.

FIG. 16A is an example top view diagram illustrating a power supply assembly prior to fabrication of winding connections as described herein.

FIG. 16B is an example top view diagram illustrating a power supply assembly including fabrication of winding connections as described herein.

FIG. 16C is an example side view diagram illustrating a power supply assembly as described herein.

FIG. 16D is an example side view diagram illustrating a power supply assembly as described through.

FIG. 17A is an example top view diagram illustrating a power supply assembly prior to fabrication of winding connections as described herein.

FIG. 17B is an example top view diagram illustrating a power supply assembly including fabrication of winding connections as described herein.

FIG. 18 is an example diagram illustrating a flow of cooling pipes as described herein.

FIG. 19 is an example diagram illustrating cooling pipes disposed between multiple instances of power supply assemblies as described herein.

FIG. 20 is an example diagram illustrating implementation of cooling pipes disposed between multiple instances of power supply assemblies as described herein.

FIG. 21A is an example top view diagram illustrating a respective heatsink assembly providing cooling to any of the assemblies as discussed herein.

FIG. 21B is an example side view diagram illustrating a respective heatsink assembly providing cooling to any of the assemblies as discussed herein. FIG. 22 is an example diagram illustrating a method as discussed herein.

The foregoing and other objects, features, and advantages of the invention will be apparent from the following more particular description of preferred examples herein, as illustrated in the accompanying drawings in which like reference characters refer to the same parts throughout the different views. The drawings are not necessarily to scale, with emphasis instead being placed upon illustrating the examples, principles, concepts, etc.

### DETAILED DESCRIPTION

A power converter assembly includes a first circuit board and a second circuit board. The first circuit board includes power converter circuitry operative to control conversion of an input voltage into an output voltage. The second circuit board is disposed substantially orthogonal to the first circuit board. The second circuit board is operative to: i) receive the output voltage, and ii) convey the output voltage to an output of the second circuit board such as a host circuit board.

Additionally, note that the power converter assembly as discussed herein can be configured to include an over-mold assembly operative to provide connectivity between the first circuit board and the second circuit board. More specifically, the over-mold assembly can be configured to include an inductor component to output the output voltage to the second circuit board based on current received by the inductor component from the input voltage.

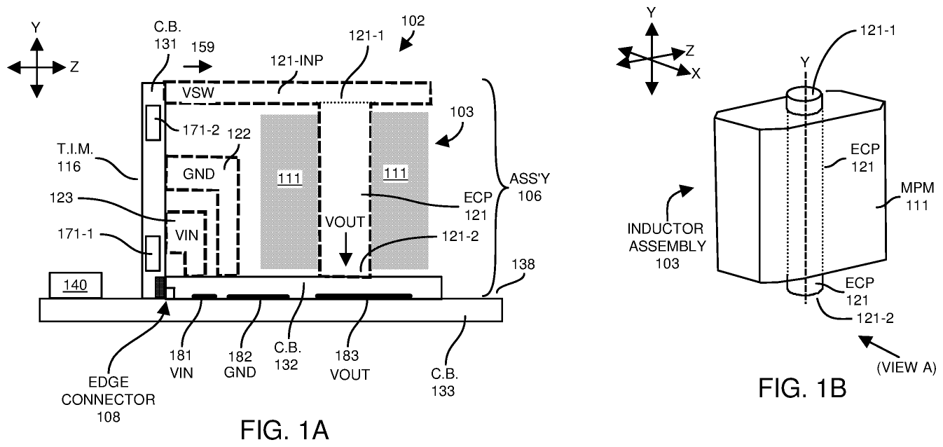

Now, more specifically, FIG. 1A is an example side view diagram of a power supply assembly including a first circuit board disposed orthogonal to a second circuit board as described herein. FIG. 1B is an example 3-D (three-dimensional) diagram of an inductor assembly in the power supply assembly of FIG. 1A as described herein.

As shown, the power supply circuit assembly 102 (such as power converter circuitry) includes assembly 106 mounted on a respective circuit board 133 (such as host substrate). The controller 140 such as including one or more circuit components is mounted to or embedded in the circuit board 133 or other suitable entity. Alternatively, the controller 140 mounted to or embedded in the circuit board 131 or circuit board 132. Thus, the controller 140 can be optionally mounted to and/or embedded in the circuit board 131 or circuit board 132.

Further in this example, the assembly 106 includes circuit board 131, circuit board 132, one or more circuit components 171, electrically conductive path 121, electrically conductive element 121-INP, electrically conductive element 122, and electrically conductive element 123. Assembly 106 further includes magnetic permeable material 111.

Note further that the assembly 106 can be configured to include insulation material such as plastic (not electrically conductive) between the components such as electrically conductive element 122, electrically conductive element 123, electrically conductive element 121-INP, magnetic permeable material 111, etc.

Each electrically conductive element or electrically conductive path as described herein is fabricated from metal or other suitable material.

The assembly 106 is mounted on (affixed to) the surface 138 of the circuit board 133.

Circuit board 131 includes one or more circuit components 171 such as component 171-1, component 171-2, etc. As previously discussed, the components 171 can be mounted to or embedded in the circuit board 131. The one or more components 171 including component 171-1, component 171-2, etc., can be configured to control conversion of an input voltage Vin into an output voltage Vout supplied from the node 121-2 to the circuit board 132.

As further shown, the circuit board 132 (such as disposed in the X-Y plane) is disposed substantially orthogonal to the circuit board 131 (such as disposed in the X-Z plane). Thus, the circuit board 131 is disposed along the Y axis. The circuit board 132 is disposed along the Z-axis.

In one example, the circuit board 132 is operative to: i) receive the output voltage Vout from the output node 121-2 (such as axial end) of the electrically conductive path 121, and via a respective electrically conductive path in the circuit board 133, ii) convey the output voltage Vout through the circuit board 132 to the output node 183 of the circuit board 132 and to the circuit board 133. The output voltage can be configured to power a respective load associated with the circuit board 133.

Inductor assembly 103 (such is disposed in the assembly 106) includes the electrically conductive path 121 disposed in the magnetic permeable material 111. For example, the electrically conductive path 121 is enveloped by the magnetic permeable material 111 for a substantial portion of the link between node 121-1 and node 121-2. The input node 121-1 of the electrically conductive path 121 is directly coupled to the node VSW node of the circuit board 131 via the electrically conductive element 121-INP.

The circuit board 131 and corresponding components control a magnitude of the input current 159 (such as sourced from the input voltage Vin and/or the ground reference potential GND) supplied from the node VSW node through the electrically conductive element 121-INP to the input node 121-1 and through the electrically conductive path 121 to the output node 121-2 to the circuit board 132.

Note further that the assembly 106 can be configured to further include multiple switches (such as component 171-1, component 171-2, etc.) operative to receive control signals from controller 140. Control signals from the controller 140 can be conveyed through the circuit board 133 to the circuit board 132. The edge connector 108 can be configured to convey information such as a magnitude of the input current 159, magnitude of the output voltage, etc., from the circuit board 131 through the circuit board 132 to the circuit board 133 and controller 140.

Yet further, as previously discussed, the circuit board 132 provides an electrically conductive path from the node 121-2 through the circuit board 132 to the output voltage node 183 (such as pad).

Also, as previously discussed, the inductor assembly 103 such as all or a portion of the electrically conductive path 121 (such as fabricated from metal or other suitable material) is enveloped by a mass of magnetic permeable material 111. Accordingly, as shown in FIG. 1B, the inductor assembly 103 includes an electrically conductive path extending along the Y-axis through the mass of magnetic permeable material 111.

As further discussed herein, note that the inductor assembly 103 (also known as inductor component) and corresponding electrically conductive paths 121-INP, electrically conductive path 122, and electrically conductive path 123 can be fabricated in an over-mold assembly 102. In other words, the over-mold assembly 102 can be configured to include an electrically conductive element 123 (such as providing connectivity between the circuit board 131 and circuit board 132), electrically conductive element 121-INP and electrically conductive path 121 (such as providing connectivity between the circuit board 131 and circuit board 132), and magnetic permeable material 111. As further discussed herein, the over-mold assembly 102 also can be configured to include one or more components such as corresponding electrically conductive path 122, electrically conductive path 123, etc.

The circuit board 132 receives the input voltage from the circuit board 133 via the input voltage node 181. The circuit board 132 conveys the received input voltage Vin received from the circuit board 133 to the electrically conductive element 123 (such as a clip or other suitable entity). The electrically conductive element 123 is operative to convey the input voltage VIN from the circuit board 132 to the circuit board 131.

Additionally, the over-mold assembly 102 can be configured to include an electrically conductive element 122 (such as providing connectivity between the circuit board 131 and circuit board 132). The circuit board 132 receives the ground reference potential from the circuit board 133 via the ground reference node 182. Via a respective circuit path, the circuit board 132 conveys the received reference voltage GND from the circuit board 133 to the electrically conductive element 122. As previously discussed, the electrically conductive element 122 conveys the GND reference voltage to the circuit board 131.

Thus, FIGS. 1A and 1B illustrate a power stage PCB (such as hosting semiconductor devices such as components 171) vertically mounted on the circuit board 131. The I/O signals associated with the controller 140 are conveyed via circuit board traces from the circuit board 133 and are routed to the power stage (such as circuit board 131) through the plated edge (edge connector 108) of the redistribution board (circuit board 132). In such an instance, there is no need for a third printed circuit board, enabling ease of manufacturing the assembly 102. The Vin and GND copper clips (such as electrically conductive element 122 and electrically conductive element 123 fabricated from metal) provide a low resistive path for input power and ground return path therefore yielding to higher efficiency with respect to a conventional power stage cooled module where these paths are provided by means of thin PCB layers.

Accordingly, in this cross-section view of FIG. 1A, a so-called power stage such as combination of circuit board 131 and corresponding components is vertically mounted with respect to the circuit board 132. The corresponding I/O signals between the circuit board 131 and circuit board 133 are routed from the circuit board 133 such as a so-called motherboard to the power stage circuit board 131 through a plated edge connector 108 of the (redistribution) circuit board 132. If desired, the input voltage power path and ground power path are provided with solid, low resistive, copper clips or other suitable entity providing low impedance.

One benefit of the assembly 106 is that the circuit board 131 and corresponding circuitry such as a so-called power stage is directly thermally accessible, without giving-up the other important features as easy manufacturing and efficiency. Multiple instances of the assembly 106 can be implemented in parallel to convert a respective input voltage to an output voltage.

FIG. 1B is an example 3-D (three-dimensional) diagram of an inductor assembly in the power supply assembly of FIG. 1A as described herein.

As previously discussed, the inductor assembly 103 as described herein includes an electrically conductive path 121 extending through the magnetic permeable material 111 from the first axial end (such as an input node 121-1) to a second axial end (such as an output node 121-2).

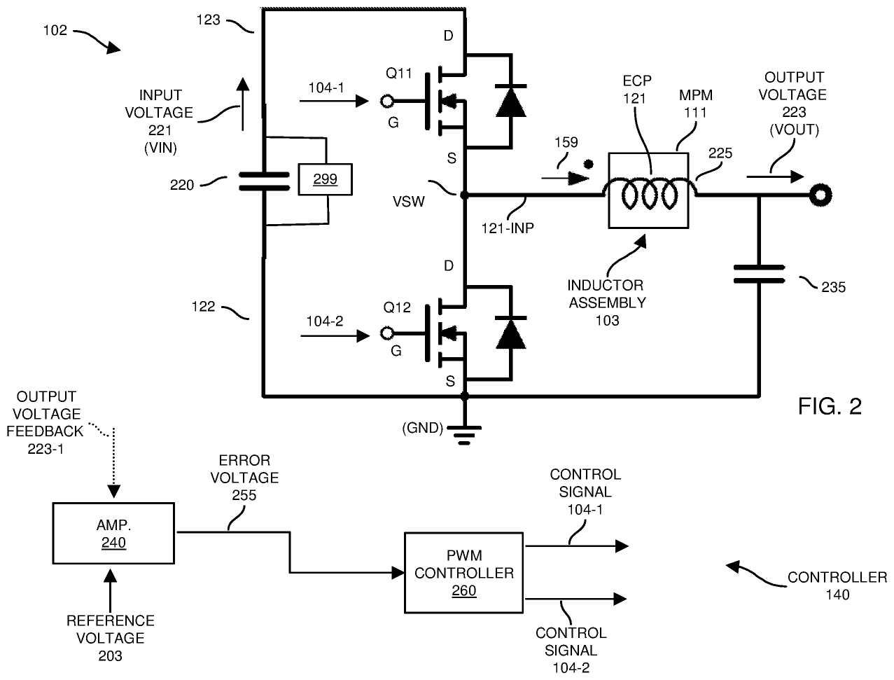

FIG. 2 is an example diagram illustrating implementation of a power converter phase to provide power to a dynamic load as discussed herein.

In this non-limiting example, the power supply circuit assembly 106 or as power converter 102 is configured as a buck converter including input voltage source 220 (such as from or on circuit board 133), switch Q11 (such as component 170-1), switch Q12 (such as component 170-2), inductor 225 (such as inductor assembly 103 or electrically conductive path 121), and output capacitor 235 (such as disposed on the circuit board 132 or circuit board 133). Note that the input voltage source 220 may include any number of input capacitors 299 disposed between the ground potential (GND) and the drain node (D) of the switch Q11. Such input capacitors can be mounted on circuit board 131, circuit board 132, or a combination of both.

Although the power converter 102 in FIG. 2 is a buck converter configuration, note that the power converter 102 can be instantiated as any suitable type of voltage converter providing regulation as described herein.

As shown, the switch Q11 is connected in series with switch Q12 on the circuit board 131 or other suitable entity between the input voltage source 220 and corresponding ground reference potential or voltage. Via switching of the switches Q11 and Q12 based on control signals 104-1 and 104-2, node 121-INP (a.k.a., VSW node) coupling the source node of switch Q11 and the drain node of switch Q12 provides current 159 through the inductor 225 (a.k.a., electrically conductive path 121), resulting in generation of the output voltage 223 (a.k.a., VOUT) supplied to the circuit board 132, which outputs the output voltage 223 (VOUT) to the circuit board 133.

In one example, the pulse width modulation controller 260 associated with the controller 140 or other suitable entity controls switching of the switches Q11 and Q12 based on one or more feedback parameters. For example, as previously discussed, the controller 140 receives output voltage feedback signal 223-1 derived from the output voltage 223 supplied to power the load 118. Via the amplifier240, the controller 140 compares the output voltage feedback signal 223-1 (such as output voltage 223 or VOUT itself or derivative signal) to the reference voltage 203. As previously discussed, the reference voltage 203 is a desired setpoint in which to control a magnitude of the output voltage 223.

Based on the comparison as provided by amplifier 240, the amplifier 240 produces a respective error voltage 255 based on the difference between the output voltage feedback signal 223-1 and the reference voltage 203. A magnitude of the error voltage varies 255 depends upon the degree to which the magnitude of the output voltage 223 is in or out of regulation (with respect to a reference voltage 203).

As further shown, the PWM controller 260 of the controller 140 controls operation of switching the switches Q11 and Q12 based upon the magnitude of the error voltage 255. For example, if the error voltage 255 indicates that the output voltage 223 (of the power converter 102) is less than a magnitude of the reference voltage 203, the PWM controller 260 increases a duty cycle of activating the high side switch Q11 (thus decreasing a duty cycle of activating the low-side switch Q12) in a respective switching control cycle.

Conversely, if the error voltage 255 indicates that the output voltage 223 (of the power converter 112) is greater than a magnitude of the reference voltage 203, the PWM controller 260 decreases a duty cycle of activating the high side switch Q11 (thus increasing a duty cycle of activating the low-side switch Q12) in a respective switching control cycle.

As is known in the art, the controller 140 can be configured to control each of the switches Q11 and Q12 ON and OFF at different times to prevent short-circuiting of the input voltage 221 (a.k.a., VIN) to the ground reference voltage. For example, when the switch Q11 is activated to an ON state, the switch Q12 is deactivated to an OFF state. Conversely, when the switch Q 11 is deactivated to an OFF state, the switch Q12 is activated to an OFF state.

Via variations in the pulse with modulation of controlling the respective switches Q11 and Q12, the controller 140 controls generation of the output voltage 121 such that the output voltage 223 remains within a desired voltage range.

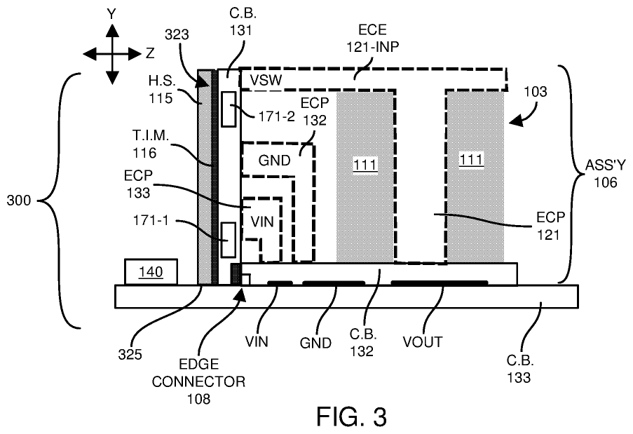

FIG. 3 is an example side view diagram of a power supply assembly as described herein.

In this example, the heatsink 115 is directly connected to the circuit board 133 via the thermal interface material 116.

In such an instance, the circuitry 300 includes an inductor assembly 103 (such as a combination of electrically conductive path 121 and magnetic permeable material 111 as well as electrically conductive element 121-INP) coupled to both the circuit board 131 and the circuit board 132. As previously discussed, the inductor assembly 103 is used to convert the input voltage VIN into the output voltage VOUT based on control of current 159 from the input voltage VIN and GND reference through an electrically conductive path 121 of the inductor assembly 103 to the circuit board 102.

The circuitry 300 further includes a heat sink assembly in which a first portion (surface 323) of the heat sink 115 is coupled to the circuit board 131 via the thermal interface material 116 (such as a thermally conductive material) providing good flow of heat from the circuit board 131 to the heatsink 115. As shown, the circuit board 131 is disposed between the heatsink 115 in the inductor assembly 103. The second portion (surface 323) of the heat sink 115 is directly coupled to the circuit board 133 as well.

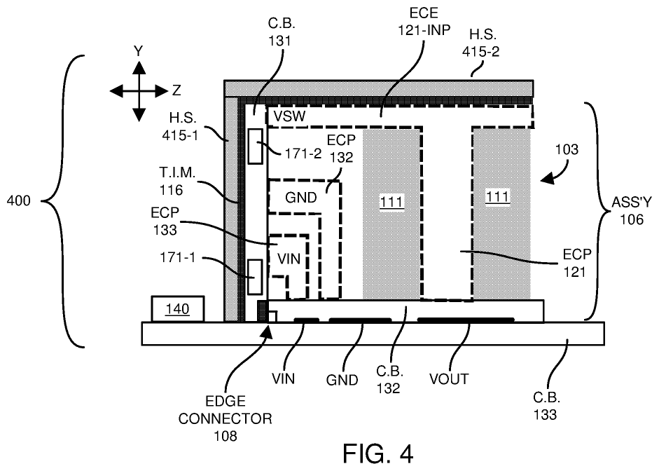

FIG. 4 is an example diagram illustrating a power supply assembly as described herein.

In this example, the heatsink assembly 415 associated with assembly 106 is L-shaped to cool down the module from two sides, yielding to even better thermal performances. A first portion the heatsink 415-1 is directly connected to the circuit board 131 via the thermal interface material 116 in a similar manner as previously discussed.

Yet further, the circuitry 400 includes an inductor assembly 103 (such as a combination of electrically conductive path 121 and magnetic permeable material 111 as well as electrically conductive element 121-INP) coupled to both the circuit board 131 and the circuit board 132.

The circuitry 400 in this example includes a heat sink assembly in which a first portion of the heat sink 415-1 is coupled to the circuit board 131 via the thermal interface material 116 (such as an insulator material) providing flow of heat from the circuit board 131 to the heatsink 415-1. As shown, the circuit board 131 is disposed between the heatsink 415-1 and the inductor assembly 103. The second portion of the heat sink 415-2 is directly coupled to the assembly 106 thermal interface material 116. In such an instance, the second portion of the heat sink 415-2 is coupled to a surface of the inductor assembly 103 in which the inductor assembly 103 is disposed between the portion of the heat sink 415-2 and the circuit board 132.

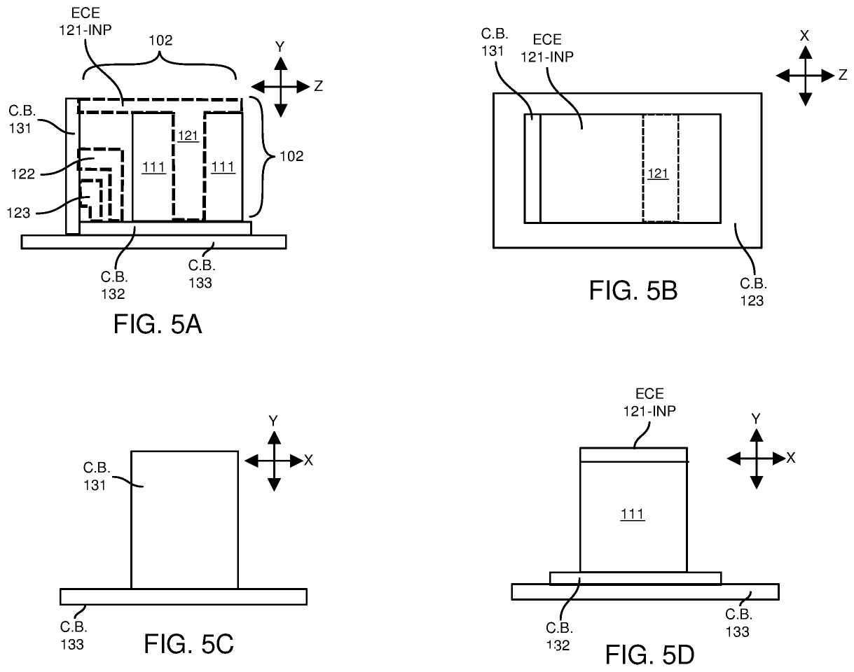

FIG. 5A is a side view diagram of a power supply assembly as described herein. FIG. 5B is a top view diagram of a power supply assembly as described herein. FIG. 5C is an example for side view diagram of a power supply assembly as described herein. FIG. 5D is an example second side view diagram of a power supply assembly as described herein.

In this example, a single-phase module is shown. Multiple instances of the single phase implementation can be extended to multiple phases in parallel.

As previously discussed, the over-mold assembly 102 provides connectivity between the circuit board 131 and the circuit board 132. The over-mold assembly 102 (a.k.a., over-molded assembly 102) includes an inductor component (such as electrically conductive paths enveloped by magnetic permeable material 111) and multiple connector components including electrically conductive element 123, electrically conductive element 122, and electrically conductive element 121-INP. The inductor component (also known as, electrically conductive path 121) is operative to output the output voltage VOUT or output voltage 223 to the circuit board 132 based on current 159 inputted to the inductor component from the input voltage VIN as previously discussed. The multiple connector components in the over mold assembly 102 include: i) the electrically conductive element 122 providing conveyance of the input voltage VIN from the circuit board 132 to the circuit board 131, and ii) the electrically conductive element 123 providing conveyance of a GND reference voltage associated with the input voltage VIN from the circuit board 132 to the circuit board 131.

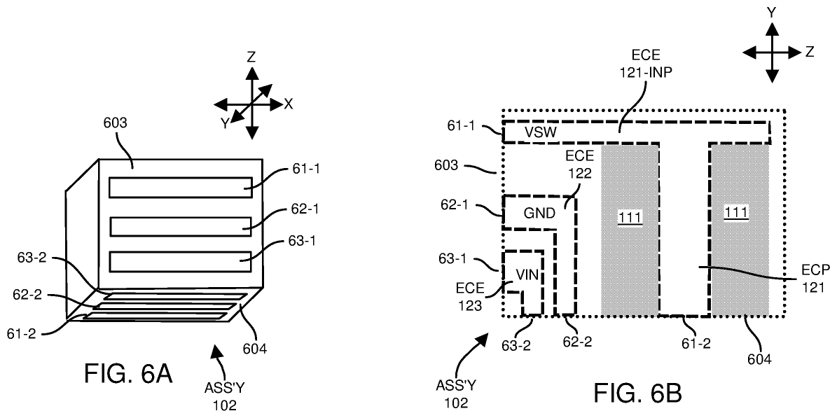

FIG. 6A is an example 3-D diagram of a circuit path assembly as described herein. FIG. 6B is an example side view diagram of the circuit path assembly of FIG. 6A as described herein.

The over-mold assembly 102 in this example includes 6 nodes (such as terminals or pads) associated with the corresponding electrically conductive paths therethrough.

For example, the over-mold assembly 102 includes a combination of the electrically conductive element 121-INP and the electrically conductive path 121 extending between the node 61-1 disposed on the surface 603 of the over mold assembly 102 to the node 61-2 disposed on a surface 604 of the over mold assembly 102. Accordingly, the combination of the electrically conductive element 121-INP and the electrically conductive path 121 disposed in the over-mold assembly 102 provides connectivity and conveyance of the current 159 between the node 61-1 to the node 61-2.

Yet further, the over-mold assembly 102 includes electrically conductive element 122 extending between the node 62-1 disposed on the surface 603 of the over-mold assembly 102 to the node 62-2 disposed on a surface 604 of the over mold assembly 102. Accordingly, the electrically conductive element 122 disposed in the over-mold assembly 102 provides connectivity and conveyance of the GND reference voltage between the node 62-2 to the node 62-1.

Still further, the over-mold assembly 102 includes electrically conductive element 123 extending between the node 63-1 disposed on the surface 603 of the over mold assembly 102 to the node 63-2 disposed on a surface 604 of the over-mold assembly 102. Accordingly, the electrically conductive element 123 disposed in the over-mold assembly 102 provides connectivity and conveyance of the input voltage VIN between the node 63-2 to the node 63-1.

Such an assembly 102 is useful because the assembly 102 itself can be used to provide connectivity between circuit board 131 and circuit board 132 as previously discussed.

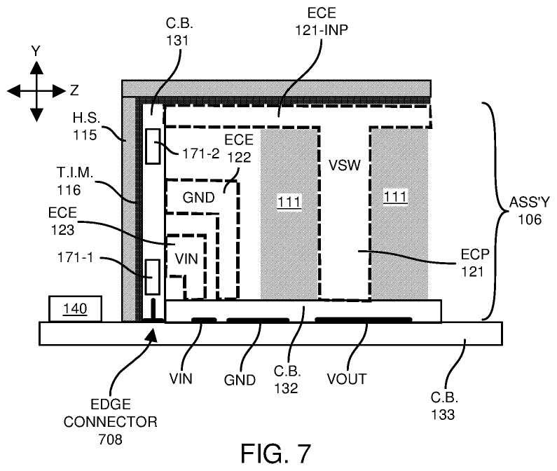

FIG. 7 is an example side view diagram illustrating implementation of a power supply assembly as described herein.

In this example, the bottom face of the power stage PCB (circuit board 131) is edge plated to include edge connector 708. In such an instance, the I/O signals are directly transferred between the circuit board 131 and circuit board 133 or circuit board 132. This alleviates the need of signals having to be conveyed between the circuit board 131 and the circuit board 133. In other words, the circuit board 132 can be bypassed.

In such an instance, the circuit board 131 can be configured to include a respective connector interface such as edge connector 708 providing connectivity of an edge of the circuit board to the circuit board 133 such as a host substrate. The connector interface (a.k.a., edge connector 708) conveys any signals received from the circuit board 133 such as a host substrate to the power converter circuitry on the circuit board 131. In a reverse direction, the connector interface (a.k.a., edge connector 708) conveys signals received from the circuit board 131 to the circuit board 133.

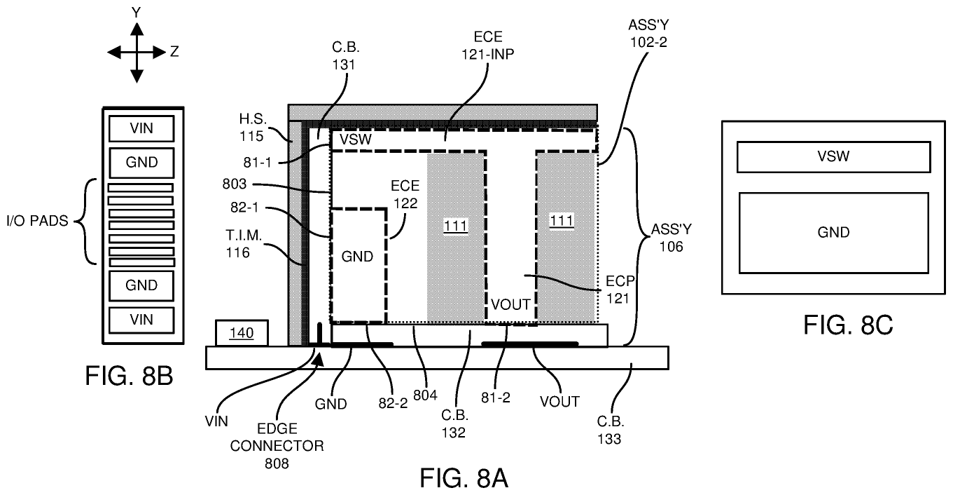

FIG. 8A is an example side view diagram illustrating implementation of a power supply assembly as described herein. FIG. 8B is an example diagram view of input-output pads associated with the power supply assembly as described herein. More specifically, the FIG. 8B is a view of an edge connector 808 providing connectivity to circuit board. FIG. 8C an example diagram illustrating a side view diagram of a circuit path assembly as described herein.

In yet another example shown in FIGS. 8A, 8B, and 8C, the edge plated bottom of the power stage PCB (circuit board 131) includes, together with the I/O signals, Vin and GND connections. This way, it is possible to avoid use of the VIN clip in the assembly 106 because the input voltage is conveyed to the circuit board 131 directly from the circuit board 133 at the edge connector 808, saving precious space which can be used to increase the inductor's dimension or to make the module (such as assembly 106) smaller. Another benefit is that the VIN loop is now so small that also the parasitic inductance of such loop is minimized, this way the low impedance allows to place lower frequency decoupling input capacitor directly on the motherboard so as power module bill of material and complexity can be reduced (i.e. only high frequency decoupling capacitor need to be mounted on the module).

More specifically, the over-mold assembly 102-2 includes a combination of the electrically conductive element 121-INP and the electrically conductive path 121 extending between the node 81-1 disposed on the surface 803 of the over mold assembly 102-2 to the node 81-2 disposed on a surface 804 of the over mold assembly 102-2. Accordingly, the combination of the electrically conductive element 121-INP and the electrically conductive path 121 disposed in the over-mold assembly 102-2 provides connectivity and conveyance of the current 159 between the node 81-1 to the node 81-2.

Yet further, the over-mold assembly 102-2 includes electrically conductive element 122 extending between the node 82-1 disposed on the surface 803 of the over-mold assembly 102-2 to the node 82-2 disposed on a surface 804 of the over mold assembly 102-2. Accordingly, the electrically conductive element 122 disposed in the over-mold assembly 102-2 provides connectivity and conveyance of the GND reference voltage between the node 82-2 to the node 82-1.

Still further, the circuit board 131 can be configured to include a connector interface 808 (such as edge connector 808) providing connectivity of an edge of the circuit board 131 to the circuit board 133 such as a host substrate, bypassing the circuit board 132. The connector interface (a.k.a., edge connector 808) is operative to convey signals (such as including the input voltage) received from the circuit board 133 to the power converter circuitry on the circuit board 131 and/or vice versa.

If desired, the connector interface can be configured to convey the input voltage VIN from can be 133 to the power converter circuitry of the circuit board 131.

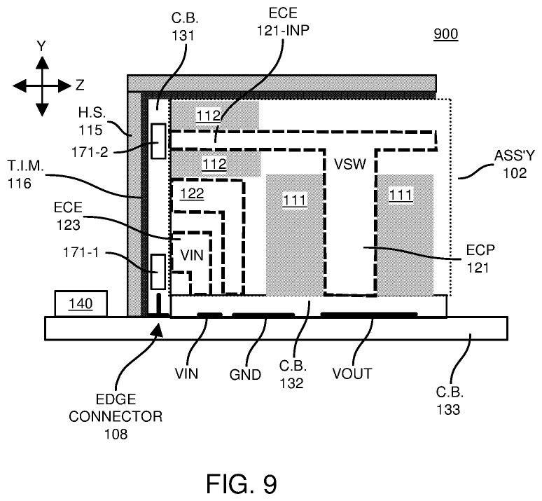

FIG. 9 is an example side view diagram illustrating implementation of a power supply assembly including multiple instances of magnetic permeability as described herein.

In yet another example, the horizontal part of the switch node connection or electrically conductive element 121-INP can be surrounded by additional magnetic material 112, in form of solid blocks or sheets, in order to provide more inductance to the system. The implementation of the circuit 900 in FIG. 9 includes 2 inductors disposed in series. For example, the first inductor is formed via the combination of electrically conductive path 121 surrounded by the magnetic permeable material 111. The second inductor is formed via the combination of electrically conductive element 121-INP surrounded by the magnetic permeable material 112.

The magnetic permeable material 111 may have a same or different magnetic permeability than the magnetic permeable material 112.

Accordingly, examples of the circuitry 900 such as a power converter assembly can be configured to include an inductor component coupled to both the circuit board 131 and the circuit board 132. The inductor component includes an electrically conductive path such as including electrically conductive element 121-INP and the electrically conductive path 121 that converts current received from the input voltage into the output voltage outputted from the electrically conductive path 121. The inductor component includes first magnetic permeable material 111 surrounding a first portion of the electrically conductive path 121. The inductor component also includes second magnetic permeable material 112 surrounding a second portion of the electrically conductive path (i.e., electrically conductive element 121-INP).

As previously discussed, in one example, a magnetic permeability of the first magnetic permeable material 111 is different than a magnetic permeability of the second magnetic permeable material 112; the first portion of the inductor component such as electrically conductive path 121 extends axially in a first direction such as along the Y-axis; the second portion of the inductor component such as the electrically conductive element 121-INP extends axially in a second direction (such as along the z-axis) different than the first direction.

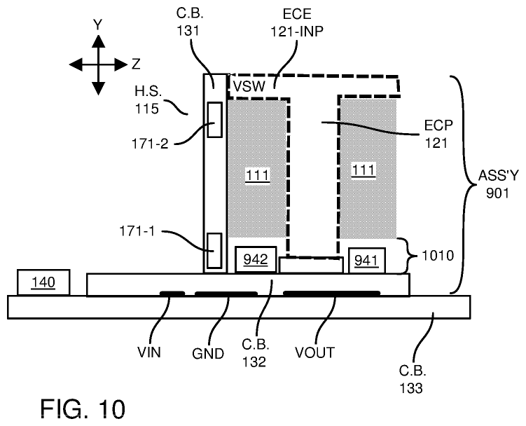

FIG. 10 is an example side view diagram illustrating implementation of the power supply assembly as described herein.

As shown in this example, circuit board 131 such as a power stage PCB is placed on the circuit board 132 such as a redistribution board. The switch node connectivity is achieved on the top plated side of the circuit board 131. The electrically conductive path 121 (a.k.a., a tubecore inductor) and corresponding magnetic permeable material 111 is lifted up or spaced from the circuit board 132 in order to accommodate output and input components 941 and 942 (such as capacitors or other suitable components).

Thus, the assembly 901 can be configured to include an inductor assembly including magnetic permeable material 111 and electrically conductive path 121. The electrically conductive path 121 and corresponding electrically conductive element 121-INP provides direct connectivity between the circuit board 131 and the circuit board 132. A spacing 1010 between the magnetic permeable material 111 and a surface of the circuit board 132 is populated with corresponding component 941 and component 942. The multiple circuit components (such as 941 and 942) are directly coupled to the surface of the second circuit board 132. As previously discussed, the circuit components 941 and 942 reside in the spacing 1010 between the magnetic permeable material and the surface of the second circuit board 132.

Accordingly, FIG. 10 shows an example where the power stage board (circuit board 131) is edge plated both on the bottom and on the top side and it is placed on top of the redistribution board (rather than on the mother-board or circuit board 133). This way, the overall footprint of the module is confined to the one of redistribution board which can therefore follow the market standards without requiring the customer to change the layout of his motherboard. One more difference with the previous examples is that the power stage PCB (circuit board 131) includes also the VIN and GND layers not requiring external clips allowing the module to be more compact. Additionally, the switch node connection is done on the top plated side of the power stage PCB. Finally, the tubecore inductor (such as electrically conductive path 121 surrounded by the magnetic permeable material 111) is lifted up in order to produce spacing 1010, accommodating components 941 and 942. Accommodate input and output capacitors. Alternatively, with an appropriate capacitor size and PCB layout, these components 941 and 942 can also be embedded directly into any of the PCBs associated with the assembly 901.

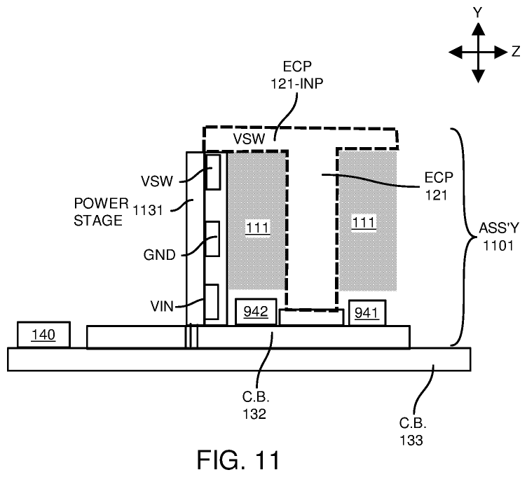

FIG. 11 is an example side view diagram illustrating implementation of a power supply assembly as described herein.

In this case, there is a desire to use a discrete power stage 1131 (like a lead frame based on providing a function such as circuit board 131) rather than embedding the semiconductor devices (such as components 171, 172, etc.) into the power stage PCB (circuit board 131). Note that the proposed aspects of assembly 1101 of FIG. 11 and corresponding discrete power stage 1131 can be applied to all previously shown examples.

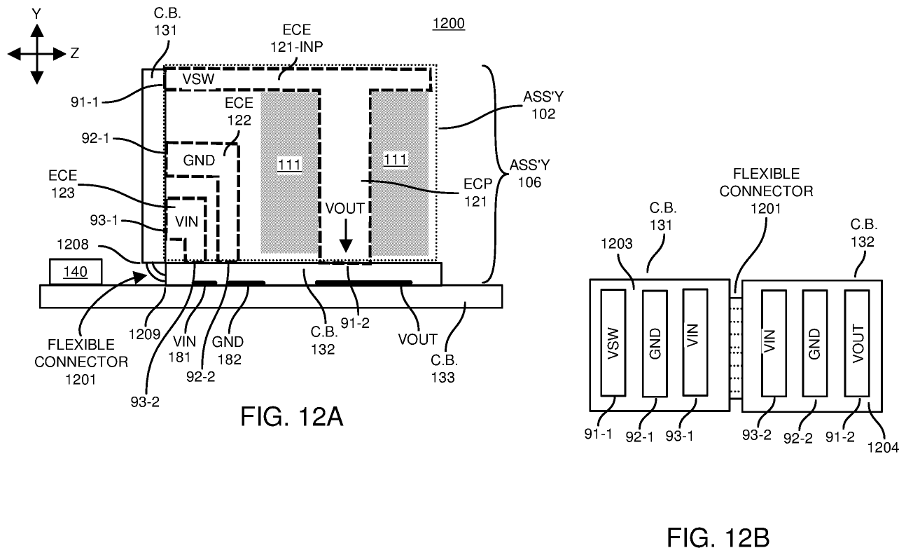

FIG. 12A is an example side view diagram illustrating implementation of a power supply assembly as described herein. FIG. 12B is an example diagram illustrating implementation of multiple circuit boards and a respective flexible connector as described herein.

As shown in FIG. 12A and FIG. 12B, the power stage PCB and the redistribution PCB can be connected through a flexible portion of PCB (such as flexible connector 1201) which embeds the copper circuit paths carrying the power stage's I/O signals.

The main benefit of this implementation is that the power stage PCB (such as circuit board 131) and the redistribution PCB (such as circuit board 132) are provided as one single pre-connected component (see FIG. 12B). This way, there are less solder connections to be performed and the module can be assembled in just a few steps.

Accordingly, referring again to FIG. 12A, the example power converter assembly 1200 includes a flexible hinge connector 1201 connected to an edge 1208 of the circuit board 131 and an edge 1209 of the second circuit board 132. The flexible hinge connector 1201 conveys signals between the first circuit board 131 and the second circuit board 132.

As further shown, the first circuit board 131 can be configured to include a first surface pad 91-1, a second surface pad 92-1, and a third surface pad 93-1. The second circuit board 132 includes a fourth surface pad 93-2, a fifth surface pad 92-2, and a sixth surface pad 91-2. Each of the surface pads is a respective node.

In the corresponding assembly 106, the surface pad 93-2 of the second circuit board 132 is operative to receive the input voltage VIN from the circuit board 133 and convey it over a first electrically conductive element 123 (electrically conductive path) to the third surface pad 93-1 of the first circuit board 131.

The surface pad 92-2 of the second circuit board 132 is operative to receive the input GROUND reference voltage potential and convey it over a second electrically conductive element 122 (electrically conductive path) to the surface pad 92-1 of the first circuit board 131.

In another example, circuit board 132 can be configured to receive input voltage VIN and ground reference potential (GROUND or GND) from the circuit board 133 via the input voltage node 181 and ground reference node 182, respectively, as previously discussed in FIG. 1A. The circuit board 132 in FIG. 12A can be configured to convey VIN and GND to circuit board 131 via flexible connector 1201. Accordingly, the assembly 102 may not need to include the electrically conductive element 122 and the electrically conductive element 123 because the flexible connector 1201 conveys these voltages from the circuit board 132 to the circuit board 131.

If desired, both the flexible connector 1201 and the electrically conductive elements 122 and 123 (present in the assembly 102) can be configured to convey the input voltage and the ground reference from the circuit board 132 to the circuit board 131. The surface pad 91-1 of the circuit board 131 is operative to output current 159 derived from the input voltage VIN and/or ground reference potential. The output current 159 is conveyed over a third electrically conductive path (such as combination of electrically conductive element 121-INP in the electrically conductive path 121) to the surface pad 91-2 of the circuit board 132. As previously discussed, the electrically conductive path 121 is an inductor component.

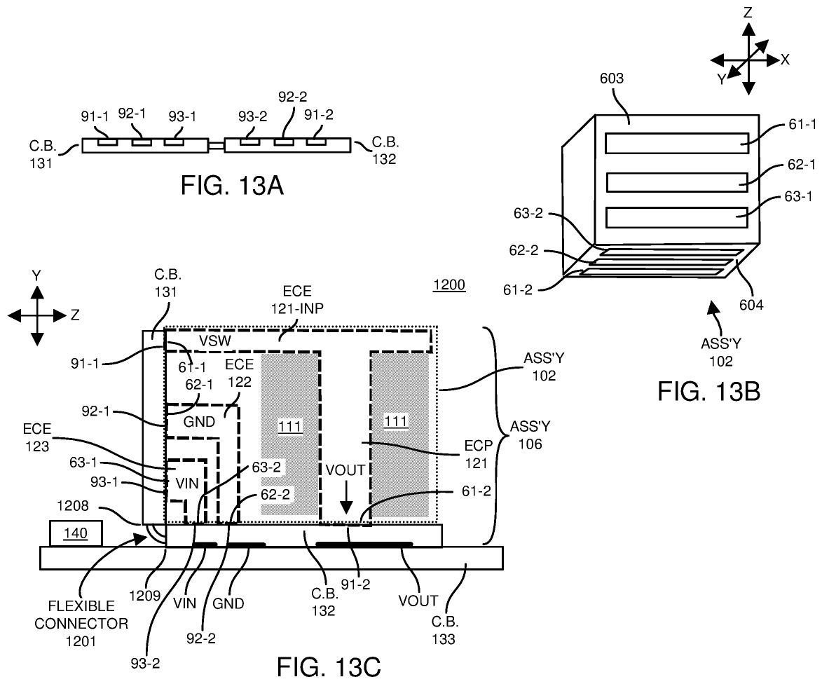

FIG. 13A is a side view diagram of a respective flexible circuit assembly as discussed herein. FIG. 13B is a three-dimensional view diagram of a respective assembly as described herein. FIG. 13C is an example diagram illustrating fabrication of a power supply assembly or power converter phase as described herein. Any number of power converter phases can be implemented in parallel to convert a respective input voltage into an output voltage.

In this example, a fabricator applies a corresponding solder paste to each of the surface pads of the circuit board 131 and circuit board 132 connected by the flexible hinge connector 1201.

Further, the fabricator electrically connects the surface pad 61-1 of the assembly 102 to the surface pad 91-1 of the circuit board 131. The fabricator electrically connects the surface pad 62-1 of the assembly 102 to the surface pad 92-1 of the circuit board 131. The fabricator electrically connects the surface pad 63-1 of the assembly 102 to the surface pad 93-1 of the circuit board 131.

The fabricator electrically connects the surface pad 61-2 of the assembly 102 to the surface pad 91-2 of the circuit board 131. The fabricator electrically connects the surface pad 62-2 of the assembly 102 to the surface pad 92-2 of the circuit board 131. The fabricator electrically connects the surface pad 63-2 of the assembly 102 to the surface pad 93-2 of the circuit board 131.

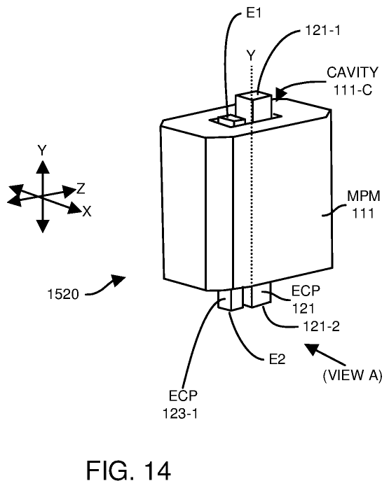

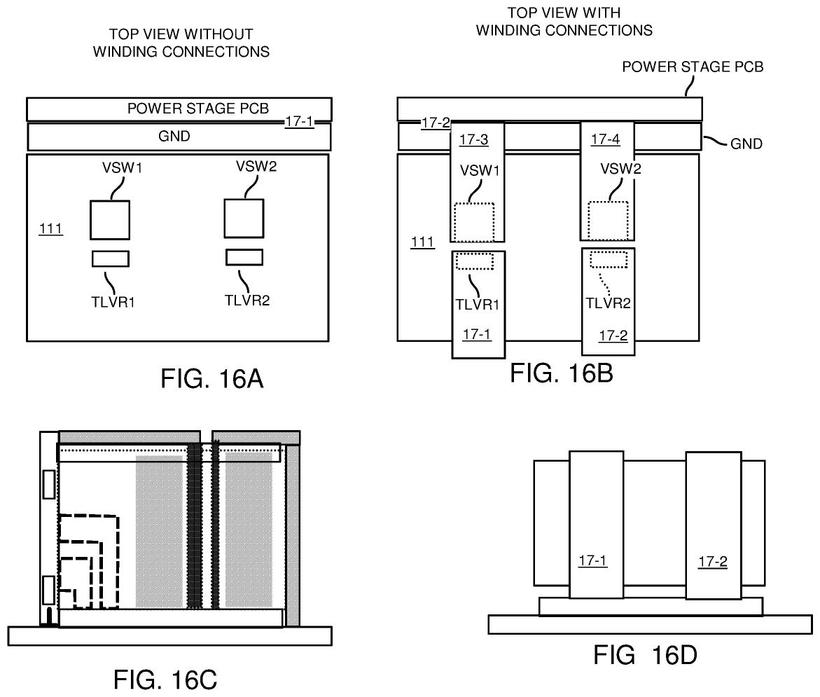

FIG. 14 shows an example of a single-phase Tubecore for TLVR systems, the dimension and reciprocal position of the two windings is up to the designer needs, moreover it must be noted that to avoid any short between the two windings there must be an electrical insulator. Multiple instances of the transformer 1520 can be implemented in a trans-inductance voltage regulator as further shown in FIG. 16.

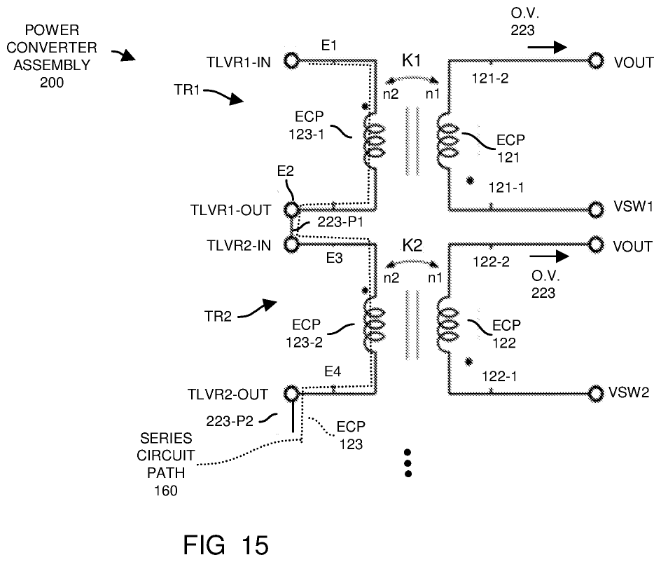

FIG. 15 is an example diagram illustrating connectivity amongst multiple power supply assemblies to provide a trans-inductance voltage regulator as described herein.

The proposed power supply as discussed herein can also be extended to a trans-inductor voltage regulator TLVR. A TLVR system which is a voltage regulator (e.g. a buck converter) where the magnetic device is no longer a single-winding inductor, but a transformer with two windings; where the primary windings constitutes the phase inductors. The secondary windings are the so called TLVR windings which are used to improve the transient performance. The secondary windings of each phase have to be series connected and their routing with the PCB must be such that it is guaranteed that the current flowing in each of them has always the same direction. The operative functioning of a TLVR system is well described in literature. However, the circuit to implement is showed in FIG. 15 for a two phases case.

For example, as shown in FIG. 15, a power converter assembly 200 such as a portion of a trans-inductance voltage regulator circuit, the electrically conductive path 121 (such as a first phase inductor) extends between the node VSW1 and the node VOUT (producing output voltage 223); the electrically conductive path 122 (such as a second phase inductor) extends between the node VSW2 and the node VOUT (producing output voltage 123).

The power converter 200 includes a series circuit path between node TLVR1-in and TLVR2-out. The series circuit path 160 (a.k.a., electrically conductive path 123) includes electrically conductive path 123-1 and the electrically conductive path 123-2 condition in series in which the electrically conductive path 223-P1 provides connectivity between node E2 (such as node TLVR1-OUT) and node E3 (such as node TLVR2-IN).

In one example, as further discussed herein, a transformer assembly is coupled to a first circuit board and a second circuit board, the transformer component including: i) a first electrically conductive path extends through magnetic permeable material, the first electrically conductive path being a primary winding operative to convert current received from the input voltage into the output voltage, and ii) a second electrically conductive path disposed in parallel to the first electrically conductive path and extending through the magnetic permeable material, the second electrically conductive path being a secondary winding magnetically coupled to the primary winding.

FIG. 16A is an example top view diagram illustrating a power supply assembly prior to fabrication of winding connections as described herein. FIG. 16B is an example top view diagram illustrating a power supply assembly including fabrication of winding connections as described herein. FIG. 16C is an example side view diagram illustrating a power supply assembly as described herein. FIG. 16D is an example side view diagram illustrating a power supply assembly as described through.

One way of implementing a TLVR system in the proposed examples is shown in FIG. 16. In this example, the primary winding VSW in each instance is connected to the power stage PCB as illustrated before, while the TLVR windings are connected to the redistribution PCB via an external copper clip. The series connection between the two TLVR windings is done with copper tracks within the redistribution PCB. As previously discussed, there is a spacing (such as including insulator material) between the phase windings and the TLVR windings.

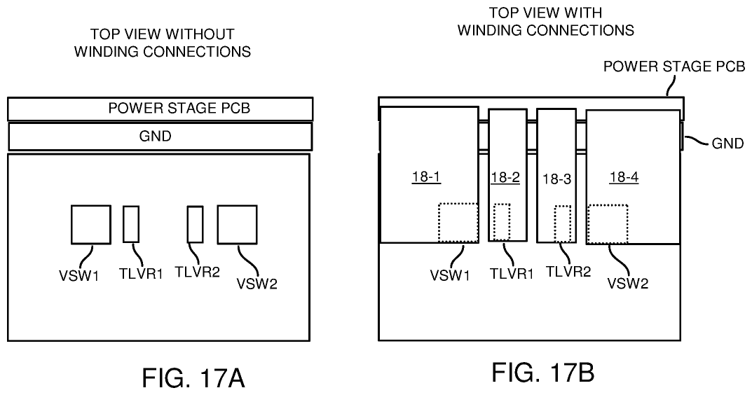

FIG. 17A is an example top view diagram illustrating a power supply assembly prior to fabrication of winding connections as described herein. FIG. 17B is an example top view diagram illustrating a power supply assembly including fabrication of winding connections as described herein.

Another TLVR circuit includes TLVR connections to the redistribution PCB through the power stage PCB.

To simplify the assembly process, the set of tubecore TLVR inductor circuit (i.e. electric circuit reported in FIG. 16) can be embedded in one single over-molded component as was shown for the tubecore reported in FIG. 6, however, now, differently, the TLVR inductor will have in addition TLVR_1_{IN} and TLVR_2ₒᵤₜ net (i.e. TLVR_1ₒᵤₜ and TLVR_2ᵢₙ connection is done into the over-molded TLVR inductor magnetic device).

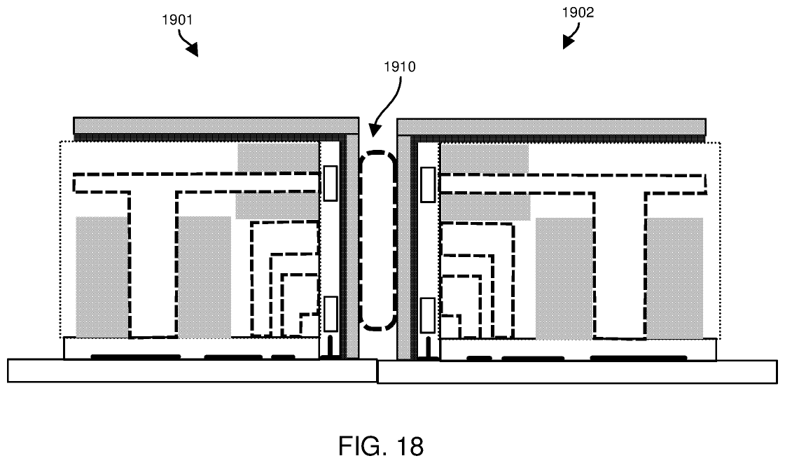

FIG. 18 is an example diagram illustrating a flow of cooling pipes as described herein.

In this example, the system includes cooling pipes 1910 running between neighboring instances of the power converter assemblies 1901 and 1902. The cooling pipes 1910 conveyed fluid to carry heat away from the respective power converter assemblies.

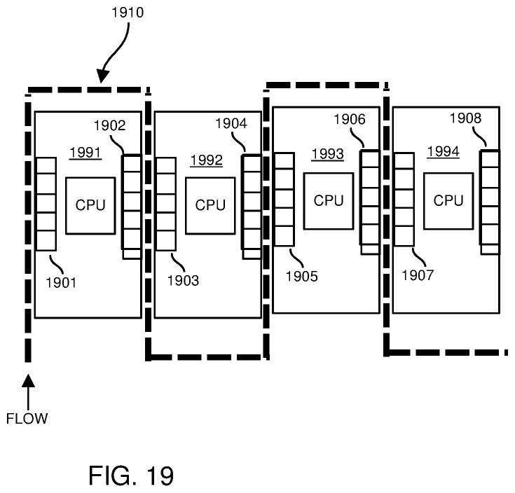

FIG. 19 is an example top view diagram illustrating cooling pipes disposed between multiple instances of power supply assemblies as described herein.

In this example, the circuit board 1991 is populated with an array of one or more power converter assemblies 1901, CPU, and an array of one or more power converter assemblies 1902. The circuit board 1992 is populated with an array of one or more power converter assemblies 1903, CPU, and an array of one or more power converter assemblies 1904. The circuit board 1993 is populated with an array of one or more power converter assemblies 1905, CPU, and an array of one or more power converter assemblies 1906, and so on.

The cooling pipes 1910 serpentine through the back to back arrays of power converter assemblies in a respective circuit boards as shown in FIG. 19. Any suitable fluid flows through the cooling pipes 1910 to a remove heat from the respective circuits.

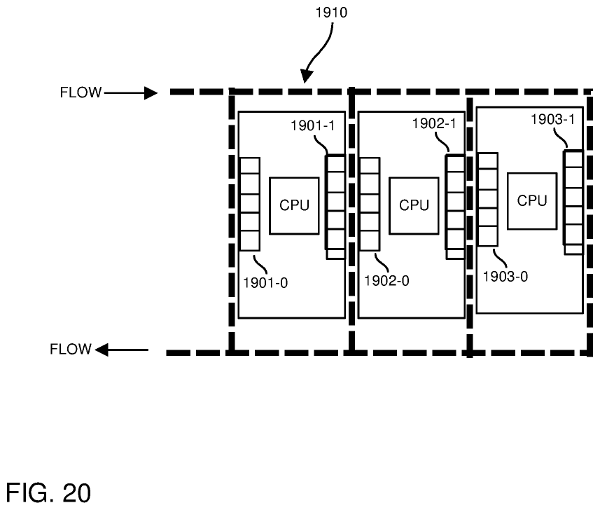

FIG. 20 is an example diagram illustrating implementation of cooling pipes disposed between multiple instances of power supply assemblies as described herein.

This example, the cooling pipes 1910 provide a ladder type connectivity amongst any number of circuit boards.

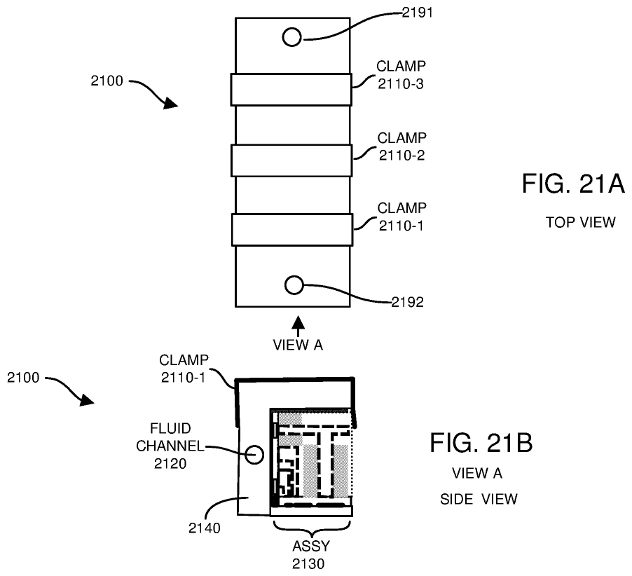

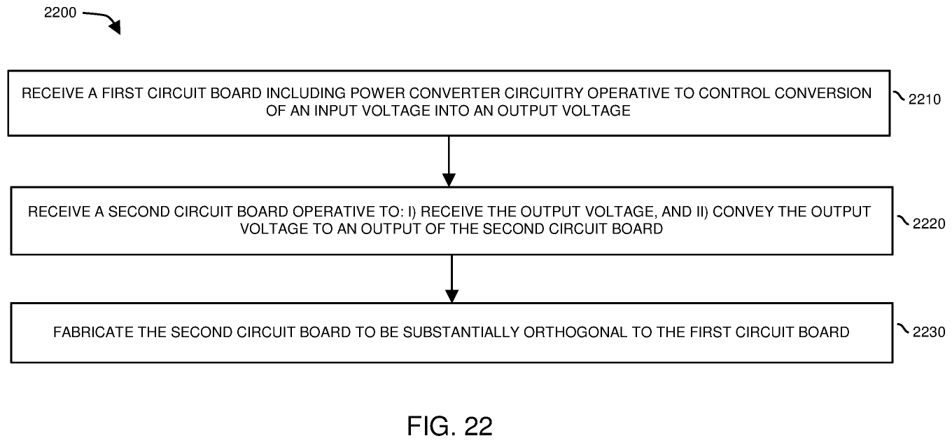

FIG. 21A is an example top view diagram illustrating a respective heatsink providing cooling to any of the assemblies as discussed herein. FIG. 21B is an example side view diagram illustrating a respective heatsink providing cooling to any of the assemblies as discussed herein.

As shown in this example of FIG. 21B, the assembly 2100 includes heatsink 2140 as well as assembly 2130. Note that the assembly 2130 (any of the assemblies as discussed herein) is in contact with the heatsink 2140. The heatsink 2140 includes a respective fluid channel 2120 to convey fluid. Via the flow of fluid through the fluid channel 2120, the heatsink 2140 carries heat away from the assembly 2130. The clamp 2110-1 can be configured to retain the assembly 2130 to the heatsink 2140.

As shown in FIG. 21A, the assembly 2100 can any include any number of clamps including clamp 2110-1, clamp 2110-2, clamp 2110-3, etc. As further shown, the assembly 2100 can be configured to include mounting holes 2191, 2192, etc., to mount the corresponding assembly 2100 to a circuit board or other entity.

FIG. 22 is an example diagram illustrating a method of controlling a power converter according to examples herein.

In processing operation 2210, a fabricator receives a first circuit board 131 including power converter circuitry (such as components 170) operative to support conversion of an input voltage into an output voltage.

In processing operation 2220, a fabricator receives a second circuit board 132 operative to: i) receive the output voltage, and ii) convey the output voltage to an output of the second circuit board 132; and

In processing operation 2230, the fabricator fabricates the assembly 102 such that the second circuit board 132 in the assembly 106 is substantially orthogonal to the first circuit board 131.

Note again that techniques herein are well suited for use in circuit applications such as those implementing power conversion. However, it should be noted that examples herein are not limited to use in such applications and that the techniques discussed herein are well suited for other applications as well.

Based on the description set forth herein, numerous specific details have been set forth to provide a thorough understanding of claimed subject matter. However, it will be understood by those skilled in the art that claimed subject matter may be practiced without these specific details. In other instances, methods, apparatuses, systems, etc., that would be known by one of ordinary skill have not been described in detail so as not to obscure claimed subject matter. Some portions of the detailed description have been presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm as described herein, and generally, is considered to be a self-consistent sequence of operations or similar processing leading to a desired result. In this context, operations or processing involve physical manipulation of physical quantities. Typically, although not necessarily, such quantities may take the form of electrical or magnetic signals capable of being stored, transferred, combined, compared or otherwise manipulated. It has been convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, as apparent from the following discussion, it is appreciated that throughout this specification discussions utilizing terms such as “processing,” “computing,” “calculating,” “determining” or the like refer to actions or processes of a computing platform, such as a computer or a similar electronic computing device, that manipulates or transforms data represented as physical electronic or magnetic quantities within memories, registers, or other information storage devices, transmission devices, or display devices of the computing platform.

While this invention has been particularly shown and described with references to preferred examples thereof, it will be understood by those skilled in the art that various changes in form and details may be made therein without departing from the spirit and scope of the present application as defined by the appended claims. Such variations are intended to be covered by the scope of this present application. As such, the foregoing description of examples of the present application is not intended to be limiting. Rather, any limitations to the invention are presented in the following claims.

1. A power converter assembly comprising:
a first circuit board including power converter circuitry operative to control conversion of an input voltage into an output voltage; and
a second circuit board disposed substantially orthogonal to the first circuit board, the second circuit board operative to: i) receive the output voltage, and ii) convey the output voltage to an output of the second circuit board.

2. The power converter assembly as in claim 1 further comprising:
an inductor assembly including an input node and an output node, the input node coupled to the first circuit board to receive input current sourced from the input voltage, the output node coupled to the second circuit board to supply the output voltage to the second circuit board.

3. The power converter assembly as in claim 2, wherein the power converter circuitry includes:
multiple switches affixed to the first circuit board, the multiple switches operative to receive control signals from a controller, the control signals operative to control conveyance of the input current through the inductor assembly to produce the output voltage supplied to the second circuit board.

4. The power converter assembly as in claim 3, wherein the inductor assembly includes:
a mass of magnetic permeable material; and
a first electrically conductive path extending through the mass of magnetic permeable material.

5. The power converter assembly as in claim 4, wherein the inductor assembly is fabricated in an over-mold assembly, the over-mold assembly including:
a second electrically conductive element providing connectivity between the first circuit board and the second circuit board, the second electrically conductive element operative to convey the input voltage from the second circuit board to the first circuit board; and
a third electrically conductive element disposed between the first circuit board and the second circuit board, the second electrically conductive element operative to convey a reference voltage from the second circuit board to the first circuit board.

6. The power converter assembly as in claim 1 further comprising:
an inductor assembly coupled to the first circuit board and the second circuit board, the inductor assembly operative to convert the input voltage into the output voltage based on control of current received from the input voltage through an electrically conductive path of the inductor assembly to the second circuit board; and
a heat sink assembly, a first portion of the heat sink assembly coupled to a surface of the first circuit board, the first circuit board disposed between the first portion of the heat sink assembly and the inductor assembly.

7. The power converter assembly as in claim 6, wherein a second portion of the heat sink assembly is coupled to a surface of the inductor assembly, the inductor assembly disposed between a second portion of the heat sink assembly and the second circuit board.

8. The power converter assembly as in claim 1 further comprising:
an over-mold assembly operative to provide connectivity between the first circuit board and the second circuit board, the over-mold assembly including an inductor assembly and multiple connector components;
wherein the inductor assembly is operative to output the output voltage to the second circuit board based on current inputted to the inductor assembly from the input voltage; and
wherein the multiple connector components include: i) a first electrically conductive element providing conveyance of the input voltage from the second circuit board to the first circuit board, and ii) a second electrically conductive element providing conveyance of a reference voltage associated with the input voltage from the second circuit board to the first circuit board.

9. The power converter assembly as in claim 1, wherein the second circuit board includes a connector interface providing connectivity of an edge of the second circuit board to the first circuit board to convey signals received from a host substrate to the first circuit board.

10. The power converter assembly as in claim 1, wherein the first circuit board includes a connector interface providing connectivity of an edge of the first circuit board to the host substrate, the connector interface operative to convey signals received from a host substrate to the power converter circuitry on the first circuit board, the second circuit board affixed to the host substrate.

11. The power converter assembly as in claim 10, wherein the connector interface is operative to convey the input voltage from the host substrate to the power converter circuitry of the first circuit board.

12. The power converter assembly as in claim 1 further comprising:
an inductor assembly coupled to the first circuit board and the second circuit board, the inductor assembly including an electrically conductive path operative to convert current received from the input voltage into the output voltage, the inductor assembly including first magnetic permeable material surrounding a first portion of the electrically conductive path, the inductor component including second magnetic permeable material surrounding a second portion of the electrically conductive path.

13. The power converter assembly as in claim 12, wherein a magnetic permeability of the first magnetic permeable material is different than a magnetic permeability of the second magnetic permeable material;
wherein the first portion of the inductor assembly extends axially in a first direction; and
wherein the second portion of the inductor assembly extends axially in a second direction different than the first direction.

14. The power converter assembly as in claim 1 further comprising:
an inductor assembly including magnetic permeable material and an electrically conductive path, the electrically conductive path providing direct connectivity between the first circuit board and the second circuit board;
a spacing between the magnetic permeable material and a surface of the second circuit board; and
multiple circuit components directly coupled to the surface of the second circuit board, the circuit components residing in the spacing between the magnetic permeable material and the surface of the second circuit board.

15. The power converter assembly as in claim 1 further comprising:
a flexible hinge connector providing connectivity between an edge of the first circuit board and an edge of the second circuit board, the flexible hinge connector operative to convey signals between the first circuit board and the second circuit board.

16. The power converter assembly as in claim 15, wherein the first circuit board includes a first surface pad, a second surface pad, and a third surface pad;
wherein the second circuit board includes a fourth surface pad, a fifth surface pad, and a sixth surface pad;
wherein the fourth surface pad of the second circuit board is operative to output the input voltage over a first electrically conductive path from the second circuit board to the third surface pad of the first circuit board;
wherein a second electrically conductive path disposed between the fifth surface pad of the second circuit board and the second surface pad of the first circuit board is operative to provide a reference voltage from the second circuit board to the first circuit board; and
wherein the first surface pad of the first circuit board is operative to output current derived from the input voltage over a third electrically conductive path to the sixth surface pad of the second circuit board, the third electrically conductive path being an inductor component.

17. The power converter assembly as in claim 1 further comprising:
a transformer assembly coupled to the first circuit board and the second circuit board, the transformer assembly including: i) a first electrically conductive path extending through magnetic permeable material, the first electrically conductive path being a primary winding operative to convert current received from the input voltage into the output voltage, and ii) a second electrically conductive path disposed in parallel to the first electrically conductive path and extending through the magnetic permeable material, the second electrically conductive path being a secondary winding magnetically coupled to the primary winding.

18. The power converter assembly as in claim 17, wherein the secondary is winding disposed in a circuit path connecting multiple secondary windings in series.

19. The power converter assembly as in claim 1 further comprising:
a heat sink assembly directly coupled to a surface of the first circuit board, the heat sink assembly including a conduit, fluid flow through the conduit operative to receive heat dissipated from the first circuit board.

20. The power converter assembly as in claim 19 further comprising:
a third circuit board including power converter circuitry operative to control conversion of the input voltage into the output voltage;
a fourth circuit board disposed substantially orthogonal to the third circuit board, the fourth circuit board operative to: i) receive the output voltage, and ii) convey the output voltage to an output of the fourth circuit board; and
wherein the heat sink assembly is directly coupled to a surface of the third circuit board, the fluid flow through the conduit operative to receive heat dissipated from the third circuit board.

21. A method comprising:
receiving a first circuit board including power converter circuitry operative to control conversion of an input voltage into an output voltage;
receiving a second circuit board operative to: i) receive the output voltage, and ii) convey the output voltage to an output of the second circuit board; and
fabricating the second circuit board to be substantially orthogonal to the first circuit board.
